(19) United States
(12) Patent Application Publication
(10) Pub. No.: US 2026/0182388 A1
(43) Pub. Date: Jun. 25, 2026

(54) WAFER-SCALE OPTICAL INTERCONNECTION SYSTEM

(71) Applicant: Volantis Semiconductor, Inc., Portland, OR (US)

(72) Inventor: Tapa GHOSH, Portland, OR (US)

(21) Appl. No.: 18/999,572

(22) Filed: Dec. 23, 2024

(51) Int. Cl. H01L 23/66; G02B 6/42; H01L 23/535; H01L 25/16

(52) U.S. Cl. CPC H10W 44/20; G02B 6/4214; H10W 20/20; H10W 90/00

(57) ABSTRACT

What is disclosed are systems for achieving wafer-scale multi-chip integration. Multiple integrated chips are coupled to each other via a wafer-scale optical interposer including waveguides and surface emitting light sources mounted thereon.

### FIELD OF THE INVENTION

The present disclosure relates generally to optical communications, and particularly to optical interconnection systems in the context of multi-chip module packaging, optical chip-to-chip interconnection, and wafer-scale integration systems.

### BACKGROUND

In order to address increasingly more complex and computationally difficult problems in many computing contexts, often multiple integrated chips are interconnected and co-operatively deployed in a single package. The problem of interconnecting the multiple integrated chips together is not trivial given the many performance metrics which are desirable to simultaneously address. A solution to chip-to-chip interconnection should ideally and simultaneously: increase the number of integrated chips that can be connected; increase the bandwidth that can be achieved in connecting the integrated chips together; reduce the cost of the interconnects; increase the energy efficiency of the interconnects; and increase the reliability of the interconnection system.

A few common, related ways of achieving these inter-chip connections include electrical wafer-scale integration techniques for interconnecting multi-chip modules (chiplet-based or monolithic), fiber-based optical interconnects, and optical wafer-scale integration.

In the context of electrical wafer-scale integration of multi-chip modules, multiple integrated chips are provided on a common wafer-sized substrate which includes wires in order to connect them together. In chiplet-based approaches, each integrated chip is a separate chip bonded and coupled to the common substrate including the wiring by which they are electrically coupled to each other. One key challenge with multi-chip approaches to wafer-scale integration is that the number of integrated chips that can be connected together is limited by the size of the package. In monolithic approaches, the entire wafer-sized substrate is used as the multi-chip module, each integrated chip being a sub-chip integrated within the wafer which includes the wiring deposited to couple the sub-chips to each other. Drawbacks to the monolithic approaches to wafer-scale integration include fabrication difficulties to achieve acceptable yield rates at such large wafer-scales and only one type of chip process may be used for the entire module, preventing integration of different sub-chip types. Both chiplet-based and monolithic approaches utilize electrical interconnects which have a fundamental limitation in the tradeoff between distance on the one hand and bandwidth density and energy efficiency on the other.

Fiber-based optical interconnects utilize optical fiber-based links to couple the multiple integrated chips to each other. Although this allows an increase in coupling distance, fiber-based links suffer from high-cost and limited bandwidth density.

Optical wafer-scale integration utilizes the approach of providing integrated photonics in the wafer itself to provide optical interconnections between the multiple integrated chips via waveguides formed in the wafer. This has the advantage of connecting integrated chips from one end of the wafer to the other end at flat energy cost.

### BRIEF SUMMARY

According to a first aspect, there is provided an optical wafer-scale interconnection system, for interconnecting a plurality of integrated chips, the system comprising: a photonic integrated wafer-scale interposer comprising: a plurality of waveguides, at least one of the plurality of waveguides including a reticle stitch portion; and a plurality of optical couplers formed within said interposer for coupling optical signals into said waveguides; a plurality of surface emitting light sources for emitting said optical signals towards said optical couplers in said interposer; and driver circuitry for directly modulating said surface emitting light sources to generate said optical signals with corresponding modulation, said driver circuitry coupled to at least one integrated chip.

In some embodiments, said at least one integrated chip controls said driver circuitry with use of electrical signals.

In some embodiments, the driver circuitry is comprised in a communicating chip mounted on said surface emitting light sources.

In some embodiments, said plurality of waveguides and said plurality of optical couplers are comprised in at least one portion of the integrated wafer-scale interposer fabricated according to a passive photonics process.

In some embodiments, the driver circuitry is comprised in a communicating chip mounted adjacent said surface emitting light sources.

In some embodiments, the communicating chip comprises an intercommunications chip mounted on said surface emitting light sources and wherein said at least one integrated chip is mounted on said intercommunications chip.

In some embodiments, said at least one integrated chip is a sub-chip integrated within a wafer-scale substrate.

In some embodiments, said communicating chip comprises said at least one integrated chip.

In some embodiments, the surface emitting light sources each comprise one of a VCSEL or a Micro-LED.

In some embodiments, the optical couplers and the waveguides are fabricated according to a Silicon Nitride photonics process.

In some embodiments, the couplers comprise grating based couplers.

In some embodiments, said optical signals generated by said surface emitting light sources are arranged to propagate in directions having non-zero vector components along directions of the waveguides into which the optical signals are coupled by the grating based couplers.

In some embodiments, the modulated couplers comprise mirror based couplers.

In some embodiments, the couplers comprise bent waveguide based couplers.

In some embodiments, the plurality of integrated chips, the photonic integrated wafer-scale interposer, the plurality of surface emitting light sources, and the driver circuitry, are arranged in an implementation with a low diameter network topology.

In some embodiments, the low diameter network topology includes at least one of a Dragonfly topology and a HyperX topology.

The foregoing and additional aspects and embodiments of the present disclosure will be apparent to those of ordinary skill in the art in view of the detailed description of various embodiments and/or aspects, which is made with reference to the drawings, a brief description of which is provided next.

### BRIEF DESCRIPTION OF THE DRAWINGS

The foregoing and other advantages of the disclosure will become apparent upon reading the following detailed description and upon reference to the drawings.

FIG. 1A is a schematic block diagram of a known chiplet-based approach to wafer-scale integration.

FIG. 1B is a schematic block diagram of a known monolithic approach to wafer-scale integration.

FIG. 1C is a schematic block diagram of a known optical fiber interconnect approach to wafer-scale integration.

FIG. 1D is a schematic block diagram of a known optical wafer-scale approach to wafer-scale integration.

FIG. 2 is a schematic block diagram of a system employing a wafer-scale optical interposer according to an embodiment.

FIG. 3A is a schematic block diagram of a system employing a wafer-scale optical interposer according to an embodiment with integrated chips or chiplets including the driver and receiver circuits.

FIG. 3B is a schematic block diagram of a system employing a wafer-scale optical interposer according to an embodiment with integrated chips or chiplets mounted on intercommunications chips.

FIG. 3C is a schematic block diagram of a system employing a wafer-scale optical interposer according to an embodiment with integrated sub-chips integrated within a wafer-scale substrate mounted on intercommunications chips.

FIG. 3D is a schematic block diagram of a system employing a wafer-scale optical interposer according to an embodiment with integrated sub-chips integrated within a wafer-scale substrate including the driver and receiver circuits.

FIG. 4A is a schematic block diagram of a grating based optical coupler of a system according to an embodiment.

FIG. 4B is a schematic block diagram of a mirror based optical coupler of a system according to an embodiment.

FIG. 4C is a schematic block diagram of a bent waveguide based optical coupler of a system according to an embodiment.

FIG. 5 is a schematic block diagram of an example topology of an implementation of a system according to an embodiment.

FIG. 6 is a schematic block diagram of another example topology of an implementation of a system according to an embodiment.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the scope of an invention as defined by the appended claims.

### DETAILED DESCRIPTION

As noted above, there are a number of known approaches to achieving wafer-scale inter-chip interconnection, including electrical wafer-scale integration techniques (chiplet-based or monolithic), fiber-based optical interconnects, and optical wafer-scale integration.

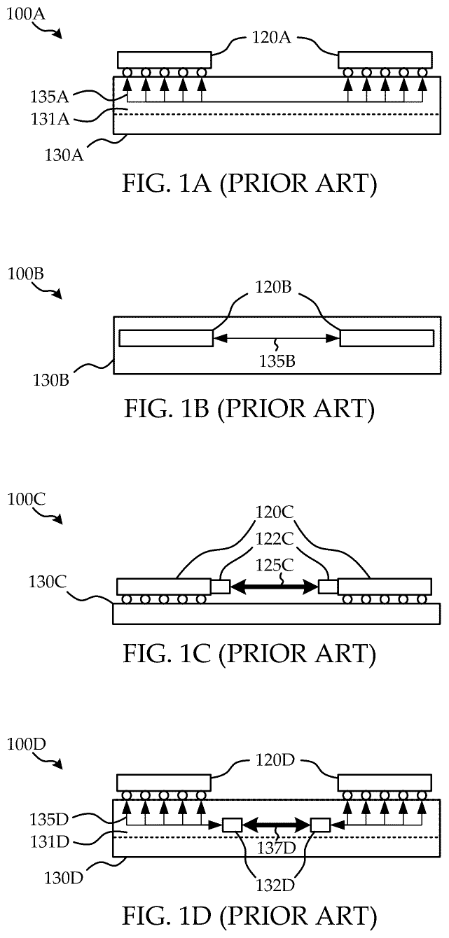

FIG. 1A illustrates a known chiplet-based approach 100A to multi-chip wafer-scale integration. As noted above, the separate multiple integrated chips or chiplets 120A are coupled to each other via electrical wires 135A included in the substrate 130A. In some implementations, an interposer 131A which includes the electrical interconnections 135A sits between the multiple integrated chips 120A and the substrate 130A.

Different materials can be used for the substrate 130A (and/or interposer 135A) as illustrated in this and the other figures, such as silicon, or an organic substrate. Silicon is generally preferred since smaller wires may be integrated therein, achieving a higher density of wiring and a higher resulting bandwidth. Silicon also has favorable mechanical properties, including having the same CTE (coefficient of thermal expansion) as the silicon chiplets 120A, and being highly flat/planar.

As noted above, one key challenge with multi-chip modules such as that depicted in FIG. 1A, is that the number of integrated chips that can be connected together is limited by the size of the package.

In response to this and other limitations, there has been increasing interest in monolithic integrated approaches to wafer-scale integration, where an entire wafer-sized substrate can be used as the multi-chip module, as exhibited by the system 100B depicted in FIG. 1B. This allows a large number of integrated chips or sub-chips 120B to be connected together via wiring 135B deposited within the substrate 130B allowing high-bandwidth communications between the sub-chips 120B.

As noted above, a drawback to the monolithic approach is that achieving acceptably high yield rates for such large wafer sizes is extremely difficult. Moreover, typically only one type of chip process may be used for the entire wafer-sized monolithic substrate 130B, eliminating the ability to simultaneously integrate chip types which require different processes, such as DRAM and IO sub-chips which would be desirable to integrate if possible. In contrast to this, in the chiplet-based approach of FIG. 1A, only tested and known good chiplets are selected to be bonded onto the large wafer-sized substrate, which improves yield rates and allows mixing and matching of different integrated chip types.

As noted above, both the chiplet-based approach of FIG. 1A and the monolithic approach of FIG. 1B utilize electrical interconnects which have a fundamental limitation in the trade-off between distance on the one hand and bandwidth density and energy efficiency on the other. For example, an electrical interconnect is limited in reach (a few millimeters), if it is high density (less than 2 μm width), and it is limited in bandwidth density (greater than 5 μm wire width) if it is long reach (tens of millimeters). Consequently, this poses a challenge to most electrical wafer-scale systems in that they are limited to mesh topologies in order to be efficient whereas many different applications would be more efficient with different network topologies, such as, for example, crossbar, star, ring, tree, and 2D torus. Many important application/workload communication patterns are not based on nearest neighbors and therefore are not well suited for such a 2D mesh topology.

In response to these and other limitations, development of optical based interconnection approaches have been made including the use of fiber-based optical interconnects as present in the system 100C depicted in FIG. 1C. Separate multiple integrated chips 120C are coupled via optical transmitters/receivers 122C over optical fiber connections 125C, all mounted on a wafer-scale substrate 130C. One advantage of optical interconnect technologies using fiber is that they are able to span very long distances (often hundreds of meters) using the same amount of energy, due to the low losses in optical fibers. As noted above, there are at least two drawbacks to optical fiber-based links including high costs due to fiber attachment implementation and limited bandwidth density due to the large size of optical fibers; only so much bandwidth may be provided through each fiber without increasing cost and complexity.

These drawbacks have motivated the approach of utilizing integrated photonics to interconnect multiple integrated chips at wafer-scale, as shown by the system 100D of FIG. 1D. Separate multiple integrated chips 120D are coupled to optical transmitters and receivers 132D via electrical connections 135D, the optical transmitters and receivers 132D transmitting and receiving optical signals over waveguides 137D formed within the substrate 130D or within an interposer 131D. As noted above, connections from one end of the wafer to the other end of the wafer should be possible at flat energy cost. Waveguides 137D and transmitters/receivers 132D may include active optical switches (for selectively switching optical signals) as well as active optical modulators such as Mach-Zehnder interferometers or micro-ring resonators, two of the most mature options. Recent implementations of this integrated photonics approach, impose a few drawbacks which limits its usefulness in practice including: high cost; thermal sensitivity; large area requirements, and waveguide losses.

The use of modulator based optical link architecture requires the implementation of expensive edge-emitting lasers which require many processing steps on expensive compound semiconductor materials. If an MRR (micro-ring resonator) based modulator is used, then it also imposes the requirement for a spectrally pure light source, which further increases laser costs. Consequently, edge emitting lasers can be as expensive as $1/laser, and if one fed four links, the net cost would be 25 cents per link, leading to costs in the thousands of dollars to match the bandwidth of HBM4. Furthermore, simply the general requirement for optical modulators drives the requirement for costly fabrication processes, since all active photonics manufacturing processes are expensive.

The edge-emitting lasers are thermally sensitive, with both their efficiency and reliability decreasing as the temperature increases. This is a problem in optical wafer-scale integration, since many compute chips are directly bonded onto the interconnect wafer at close proximity, generating large amounts of heat. Micro-ring resonators are also thermally sensitive, being generally unstable with temperature, and thus requiring heaters to stabilize their temperature, which decreases energy efficiency. Moreover, due to the MRR's requirements for spectral purity, the edge-emitting lasers are required to be spectrally pure lasers which are even more thermally sensitive.

Mach-Zehnder interferometers require an extremely large amount of area, in some cases as large an area as ˜250 μm×500 μm, or even larger. This limits both energy efficiency as well as the achievable bandwidth density. Furthermore, coupling edge-emitting lasers to the waveguide wafer also tends to limit the laser power available per unit area. Although not a large constraint, on a wafer-scale system where area matters, this can become relevant.

Although optics in the ideal case can be thought of as independent of distance, in practice the losses in the waveguide create a distance dependence. Most active photonics processes (e.g. SOI) do not have low waveguide losses, a consequence of which is that the waveguides associated therewith can have as much as 0.5 dB/cm of loss which for a ˜200 mm or 20 cm run length, is about 10 dB of total loss. Other losses associated with the active photonics optical layer include 0.08 dB loss per Mach-Zehnder interferometer, 0.028 dB per crossing, and 0.004 dB per reticle crossing. It is not trivial to reduce these losses, since the requirement for optical modulators drives the need for an active photonics process.

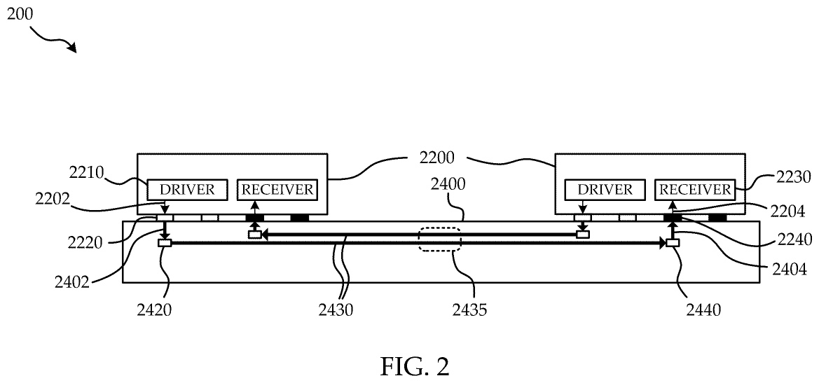

A wafer-scale optical interconnection system 200 according to an embodiment of the present disclosure is illustrated in FIG. 2. The wafer-scale optical interconnection system of FIG. 2 interconnects multiple integrated chips at wafer-scale without relying on bulky expensive optical fiber interconnects, nor on the expensive, lossy, and thermally dependent waveguides and active optical elements associated with integrated active photonics, mitigating many of the problems noted above with known approaches.

The system 200 includes a photonic integrated wafer-scale interposer 2400 in which waveguides 2430 have been formed and on which separate surface emitting light sources 2220 and optical receivers 2240 are mounted. The interposer 2400 substrate material may be silicon or glass which is more cost effective and readily available at wafer scale. Mounted adjacent to or on the surface emitting light sources 2200 and optical receivers 2240 are communicating chips 2200, each of which is capable of transmitting and receiving signals from other communicating chips 2200 via driver and receiver circuits 2210 2230 or transceiver circuits (capable of both driving and receiving) comprised in each communicating chip 2200.

The surface emitting light sources 2220 are driven via electrical signaling 2202 controlled by driver circuits 2210 of the communicating chips 2200. The communicating chip 2200, when operating to transmit optical signals, directly modulates the surface emitting light source 2220 to emit light 2402 with an output power appropriately modulated for optical signalling toward the interposer 2400. The waveguides 2430 integrated within the photonic integrated wafer-scale interposer 2400 span the interposer 2400 between the communicating chips 2200 for carrying optical signals therebetween. Light couplers 2420 coupled to the waveguides 2430 couple light 2402 emitted from the surface emitting light sources 2220 into the waveguides 2430. Optical signals traverse the waveguides 2430, including regions 2435 which comprise reticle stitches, due to the overall length of some of the waveguides 2430 being wafer-scale, and are coupled by couplers 2440 which couple the light 2404 from the waveguides 2430 of the photonic integrated wafer-scale interposer 2400 toward a coordinate optical receiver 2240 e.g. a photodiode. The couplers 2420 2440 may be, for example, grating couplers, mirrors, or bent waveguides, as described in more detail below, or any other optical coupler. The optical receiver 2240 converts the light 2404 it receives into an electrical signal 2204. The communicating chips 2200, when operating to receive optical signals, receive electrical signaling 2204 from the optical receiver 2240 at the receiver circuit 2230.

The surface emitting light sources 2220 need not be spectrally pure and can be implemented using relatively inexpensive VCSELs, PCSELs, Micro-LEDs, nanoLEDs, nano-antenna coupled LEDs, nanowire lasers, quantum dot lasers, quantum dot VCSELs, and others. In contrast to indirect modulation which modulates a pre-existing optical signal, e.g. MZI or MRR operating on a continuous wave laser signal, in direct modulation, the source of light, here the surface emitting light source, is itself modulated, i.e. the surface emitting light source's generation of optical power itself is modulated in accordance with the desired modulated envelope.

The waveguides 2430 may be fabricated according to any photonic integrated chip fabrication process including passive SOI or Silicon Nitride. In some embodiments, the interposer utilizes SOI and in particular passive SOI variants, which have much lower losses than active SOI platforms. In some embodiments, the waveguides and couplers are formed within portions of the interposer which have been fabricated according to a passive photonic integrated chip fabrication process, while other portions of the interposer may include active optical components or portions fabricated according to an active photonic integrated chip fabrication process. In some embodiments, the interposer utilizes Silicon Nitride waveguides on Silicon, or Silicon Nitride waveguides on glass, which as mentioned above is cheaper, and can be more easily scaled to larger than wafer sizes, moreover, it has a CTE that allows for easier matching to external components. With Silicon Nitride, there are very low losses which is important for long distance optical propagation (i.e. wafer scale) and it is transparent to a large window of wavelengths, including 850 nm or lower, in which many high quality surface emitting light sources transmit, and for Silicon is not transparent.

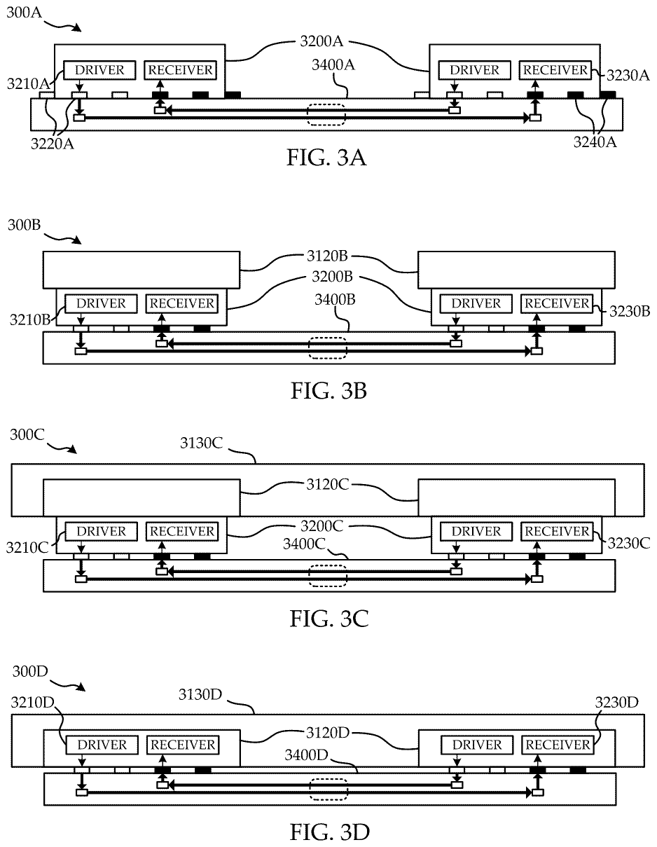

As shown in the system 300A of FIG. 3A, in some embodiments, the communicating chips 2200 are the multiple integrated chips 3200A (e.g. compute chips, memory chips, etc.) for which interconnection is being provided by the interposer 3400A. In such embodiments, the driver 3210A and receiver 3230A circuits (or transceivers) are formed within the integrated chips or chiplets 3200A themselves and are controlled thereby in order to encode or decode the communications respectively to be sent or received. Although in some embodiments the integrated chips 3200A may be mounted on the surface emitting light sources and optical receivers, as illustrated in FIG. 3A, any of the surface emitting light sources 3220A and/or optical receivers 3240A may be mounted adjacent the integrated chips 3200A which may be mounted directly on the interposer 3400A.

As shown in the system 300B of FIG. 3B, in some embodiments each of the multiple integrated chips 3120B for which interconnection is provided is mounted on the communicating chips 2200 which serve as intercommunications chips 3200B, each including driver 3120B and receiver 3230B (or transceiver) circuitry, between the integrated chips 3120B and the surface emitting light sources, optical receivers, and interposer 3400B structure. In some embodiments, the intercommunications chips 3200B are 3D integrated with the integrated chiplets 3120B with use of through silicon vias (TSVs) and are controlled thereby in order to encode or decode the communications respectively to be sent or received. Although in some embodiments the integrated chiplets 3120B may be mounted on the intercommunications chips 3200B, as illustrated in FIG. 3B, they may be integrated side-by-side and adjacent to them, each of which may be mounted directly on the interposer 3400A or on the surface emitting light sources and optical receivers.

As shown in the system 300C of FIG. 3C, in some embodiments each of the multiple integrated chips for which interconnection provided is an integrated sub-chip 3120C of a wafer-scale substrate 3130C which itself is mounted on the communicating chips 2200 which serve as intercommunications chips 3200C, each including driver 3120C and receiver 3230C (or transceiver) circuitry, between the integrated chips 3120C and the surface emitting light sources, optical receivers, and interposer 3400C structure. The integrated sub-chips 3120C control intercommunications chips 3200C in order to encode or decode the communications respectively to be sent or received.

As shown in the system 300D of FIG. 3D, in some embodiments the communicating chips 2200 are the multiple integrated chips (e.g. compute chips, memory chips, etc.) and are sub-chips 3120D of a wafer-scale substrate 3120D for which interconnection is provided by the surface emitting light sources, optical receivers, and interposer 3400D structure. In such an embodiment, the driver 3210D and receiver 3230D circuits (or transceivers) are formed within the integrated chips or sub-chips 3120D themselves and are controlled thereby in order to encode or decode the communications respectively to be sent or received.

In some variants of FIGS. 3C and 3D the optical wafer system including the interposer, optical receivers, surface emitting light sources, and in some cases separate communications chips, may be bonded to the wafer scale substrate with the compute and/or memory etc. sub-chips (compute wafer), while in other embodiments, the optical wafer system may be grown on the compute wafer or vice versa.

Although the surface emitting light sources of FIGS. 3A-3D have been illustrated as being mounted to the communicating chips, either adjacent to them or between them and the interposer, in some embodiments the surface emitting light sources are formed, mounted, grown or otherwise integrated within the communicating chips themselves. In the context of the relaxed spectral requirements for the surface emitting light sources of the embodiments, fabrication requirements for whatever integration technique utilized will be more forgiving than would otherwise have been required.

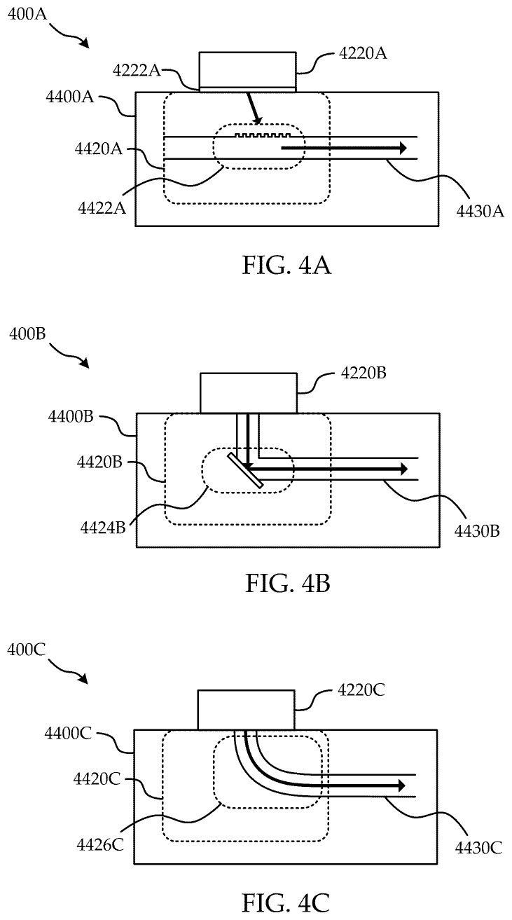

As shown in the detailed view 400A of FIG. 4A, in some embodiments the couplers 2200 are grating based couplers 4420A comprising a grating 4422A in the interposer 4400A for redirecting the light from the surface emitting light source 4220A along the waveguide 4430A. Although gratings have low coupling efficiency compared to other options, gratings are relatively straightforward to fabricate within the interposer 4400A. In some embodiments, to increase coupling efficiency the light emitted from the surface emitting light source 4220A is angled away from the plane perpendicular to the waveguide axis, toward a direction of intended light propagation through the waveguide. In some embodiments, the surface emitting light source 4220A is fabricated so as to have an off-axis beam (“off” relative to the axis perpendicular to the mounting “surface”) while in others, a 90° surface emitting light source is mounted on an off-axis micro-lens which appropriately redirects the emitted light at some angle. In some embodiments, an off-axis diffractive lens 4222A between the interposer 4400A and the surface emitting light source 4220A is used to redirect the light from the surface emitting light source 4220A. Alternatively, an angled facet on the surface of the interposer 4400A can give rise to the angled emission of light toward the grating 4422A.

As shown in the detailed view 400B of FIG. 4B, in some embodiments the couplers 2200 are mirror-based couplers 4420B comprising a mirror 4424B in the interposer 4400B for redirecting the light from the surface emitting light source 4220B along the waveguide 4430B. Although mirrors have much better coupling efficiency than gratings, mirrors pose a much greater challenge to fabricate within the interposer 4400B.

As shown in the detailed view 400C of FIG. 4C, in some embodiments the couplers 2200 are bent waveguide based couplers 4420C comprising a bent waveguide section 4426C in the interposer 4400C for redirecting the light from the surface emitting light source 4220C along the waveguide 4430C. Although bent waveguides have much better coupling efficiency than the other options, bent waveguides pose a great challenging to fabricate within the interposer 4400C.

In some embodiments, the surface emitting light sources 2220 comprise VCSELs (e.g. single mode, single polarization, or multi-aperture VCSELs), the optical couplers 2420 2440 comprise grating couplers, and the waveguides 2430 comprise silicon nitride waveguides.

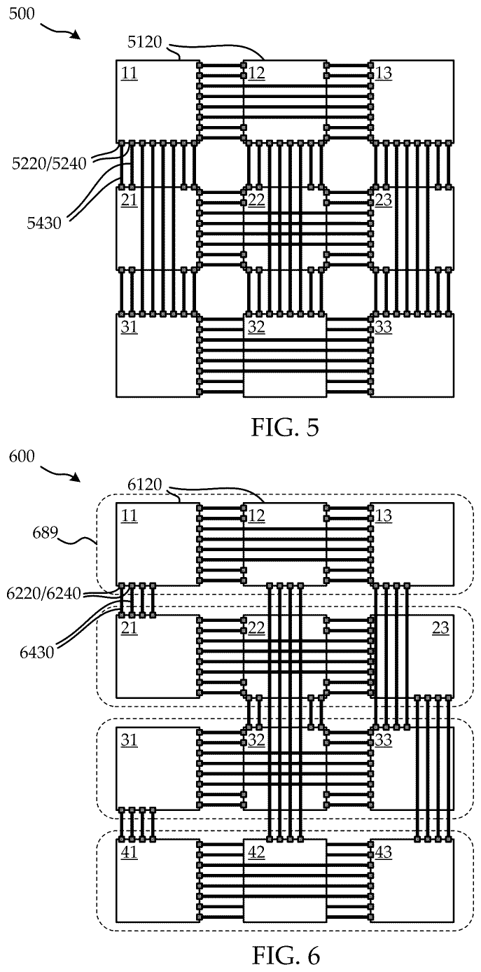

With reference to FIG. 5, a system 500 according to an embodiment having an example HyperX topology implementation will now be discussed. The multiple integrated chips 5120 for which interconnection is being provided are coupled as described above via driver and receiver circuitry, surface emitting light sources and optical receivers 5220/5240 coupled together via couplers and waveguides 5430. As can be seen in FIG. 5, chips are coupled to their neighbors via a set number of straight waveguide interconnections (e.g. four) and where present, are also coupled to their next to nearest neighbors with the same number of interconnections. For example, chip 21 is coupled to chips 11, 22, and 31 via four interconnections, and is also coupled to chip 23 via four interconnections. Some of the reasons why a HyperX topology is well suited to optical wafer-scale system include: high waveguide density; avoidance of waveguide bends; and minimizes the network diameter which minimizes the number of optical to electrical conversions and vice versa.

With reference to FIG. 6, a system 600 according to an embodiment having an example Dragonfly topology implementation will now be discussed. The multiple integrated chips 6120 for which interconnection is being provided are coupled as described above via driver and receiver circuitry, surface emitting light sources and optical receivers 6220/6240 coupled together via couplers and waveguides 6430. As can be seen in FIG. 6, chips are grouped such that chips in each group 689 are coupled to each other according to a local topology, for example, in FIG. 6 each chip is coupled to every other chip of its group via a set number of straight waveguide interconnections (e.g. four). Each group 689 of chips is also coupled to every other group of chips, in this example, with the same number of interconnections. For example, chip 21 of the second row group is coupled to chips 22 and 23 (which are also coupled to each other) each via four interconnections, and is also coupled to chip 11 of the first row group of chips via four interconnections, thereby coupling the first row group of chips and the second row group of chips. The Dragonfly topology is well suited to implementation of optical wafer-scale systems for many of the reasons why HyperX is well suited, and in fact low diameter network topologies in general are well suited to implement the systems disclosed herein. It should be understood that depending upon the particular architecture implemented, any appropriate topology may be provided by the systems described herein.

The various individual integrated chips of FIGS. 2, 3A-3D, and 5 may be mounted using any acceptable technique including solder bonding, thermocompression, hybrid bonding, laser-assisted bonding, thermosonic bonding, among others. With respect to the surface emitting light sources 2220, some preferred bonding methods include variants of flip chip bonding, micro-transfer printing, and laser-induced forward transfer.

Although each waveguide has been illustrated as coupled to a single surface emitting light source or a single optical receiver, in some embodiments, multiple devices may be coupled to the same waveguide via multiplexing and demultiplexing, for multiple simultaneous channel use, for example, multiple polarizations or wavelengths, increasing bandwidth density.

The systems of the present disclosure and illustrated in FIGS. 2, 3A-3D, and 5 mitigate a number of problems associated with known approaches as outlined above. Costs are reduced through the use of directly modulated surface emitting light sources such a VCSELs and Micro-LEDs which are very inexpensive in comparison to edge-emitting lasers, and even more so in comparison to those required to have higher spectral purity. It should be understood that direct modulation substantially removes the need for spectral purity since there is an absence of MZIs and MRRs which otherwise would require it. Moreover, embodiments employing waveguides and couplers in the passive portions of the photonic integrated wafer-scale interposer do not require active optical components, relying only on passive photonics processes for the structures guiding and coupling the optical signals which are much cheaper to fabricate than those requiring active optical process fabrication. With respect to thermal sensitivity, it should be noted that many types of the surface emitting light sources may be fabricated to exhibit thermal stability within chosen temperature ranges, e.g. VCSELs may be tuned to operate with thermal stability at relatively high temperatures. Moreover, since the systems are absent MRRs which are often employed in active photonics architectures, thermal sensitivity issues associated therewith are avoided. With respect to area, the use of direct modulation of the surface emitting light sources eliminates the need for optical modulators which solves the area overhead issue associated with active photonics architectures. Although electronic driver circuits are required for the surface emitting light sources, these can be made relatively compact, around e.g. 20 μm×20 μm, due to the low parasitics of the proposed stackup. This compares extremely favorably to Mach-Zehnder interferometers, which are generally on the order of ˜250 μm×500 μm. Incidentally, although micro-ring resonators are much smaller, and are of similar size to driver circuits, as indicated above they place requirements for spectrally pure (i.e. expensive and thermally sensitive) lasers. It should be noted that in embodiments utilizing grating couplers, there is a modest requirement for spectral purity for the surface emitting light sources (on the order of 10 s of nanometers in range within which inexpensive VCSELs fall) but nowhere near that required for MRRs (on the order of sub 0.1 nm linewidth). Incidentally, mirror and bent waveguide based couplers have very wide spectral ranges on the order of hundreds of nanometers.

It should also be noted that in various systems discussed herein, the surface emitting light sources sit below the direct modulation driver circuitry, while the optical receivers sit below the receiver circuitry, freeing up the available area for said circuitry, further improving the achievable bandwidth density.

With respect to waveguide losses, because the architecture of the system 200 does not have any active components in the waveguide layers of the interposer, this allows for the use of photonics processes that have lower losses, e.g. silicon nitride waveguide processes or a passive SOI process. Such waveguides can have losses 10-100× lower than the losses in active photonics platforms. In hybrid systems employing regions with both active and passive photonics platforms, the overall system benefits from the lower losses imparted by the regions, waveguides, and couplers employing passive photonics.

Finally, it should be noted that providing the use of direct modulation, in addition to removing the requirement for spectral purity, also provides energy and reliability advantages, reducing the required energy per layer while simultaneously gaining the benefits of increased reliability of the emitting light sources due to that reduction in required power output.

While particular implementations and applications of the present disclosure have been illustrated and described, it is to be understood that the present disclosure is not limited to the precise construction and compositions disclosed herein and that various modifications, changes, and variations can be apparent from the foregoing descriptions without departing from the spirit and scope of an invention as defined in the appended claims.

What is claimed is:

1. An optical wafer-scale interconnection system, for interconnecting a plurality of integrated chips, the system comprising:
a photonic integrated wafer-scale interposer comprising:
a plurality of waveguides, at least one of the plurality of waveguides including a reticle stitch portion; and
a plurality of optical couplers formed within said interposer for coupling optical signals into said waveguides;
a plurality of surface emitting light sources for emitting said optical signals towards said optical couplers in said interposer; and
driver circuitry for directly modulating said surface emitting light sources to generate said optical signals with corresponding modulation, said driver circuitry coupled to at least one integrated chip.

2. An optical wafer-scale interconnection system according to claim 1, wherein said at least one integrated chip controls said driver circuitry with use of electrical signals.

3. An optical wafer-scale interconnection system according to claim 1, wherein said plurality of waveguides and said plurality of optical couplers are comprised in at least one portion of the integrated wafer-scale interposer fabricated according to a passive photonics process.

4. An optical wafer-scale interconnection system according to claim 1, wherein the driver circuitry is comprised in a communicating chip mounted on said surface emitting light sources.

5. An optical wafer-scale interconnection system according to claim 1, wherein the driver circuitry is comprised in a communicating chip mounted adjacent said surface emitting light sources.

6. An optical wafer-scale interconnection system according to claim 4, wherein the communicating chip comprises an intercommunications chip mounted on said surface emitting light sources and wherein said at least one integrated chip is mounted on said intercommunications chip.

7. An optical wafer-scale interconnection system according to claim 6, wherein said at least one integrated chip is a sub-chip integrated within a wafer-scale substrate.

8. An optical wafer-scale interconnection system according to claim 4, wherein said communicating chip comprises said at least one integrated chip.

9. An optical wafer-scale interconnection system according to claim 8, wherein said at least one integrated chip is a sub-chip integrated within a wafer-scale substrate.

10. An optical wafer-scale interconnection system according to claim 1, wherein the surface emitting light sources each comprise one of a VCSEL or a Micro-LED.

11. An optical wafer-scale interconnection system according to claim 1, wherein the optical couplers and the waveguides are fabricated according to a Silicon Nitride photonics process.

12. An optical wafer-scale interconnection system according to claim 1, wherein the couplers comprise grating based couplers.

13. An optical wafer-scale interconnection system according to claim 12, wherein said optical signals generated by said surface emitting light sources are arranged to propagate in directions having non-zero vector components along directions of the waveguides into which the optical signals are coupled by the grating based couplers.

14. An optical wafer-scale interconnection system according to claim 1, wherein the modulated couplers comprise mirror based couplers.

15. An optical wafer-scale interconnection system according to claim 1, wherein the couplers comprise bent waveguide based couplers.

16. An optical wafer-scale interconnection system according to claim 1, wherein the plurality of integrated chips, the photonic integrated wafer-scale interposer, the plurality of surface emitting light sources, and the driver circuitry, are arranged in an implementation with a low diameter network topology.

17. An optical wafer-scale interconnection system according to claim 16, wherein the low diameter network topology includes at least one of a Dragonfly topology and a HyperX topology.
